(19) United States
(12) Patent Application Publication
(10) Pub. No.: US 2026/0114260 A1
(43) Pub. Date: Apr. 23, 2026

(54) SEMICONDUCTOR PACKAGES AND METHODS OF FORMATION

(71) Applicant: Taiwan Semiconductor Manufacturing Company, Ltd., Hsinchu (TW)

(72) Inventors: Shih-En LAI, Taichung City (TW); Chan-yu HUNG, Tainan City (TW); Fei-Yun CHEN, Hinchu (TW); Wen Han HUNG, Tainan City (TW)

(21) Appl. No.: 18/918,464

(22) Filed: Oct. 17, 2024

(51) Int. Cl. H01L 23/528; H01L 21/306; H01L 21/321; H01L 21/768; H01L 23/00; H01L 23/532; H01L 25/065; H01L 25/18

(52) U.S. Cl. CPC H10W 20/435; H10P 50/642; H10P 52/403; H10W 20/076; H10W 20/092; H10W 20/48; H10W 80/312; H10W 80/327; H10W 90/00; H10W 90/792

(57) ABSTRACT

One or more dielectric inserts are formed in a through-substrate interconnect structure to prevent, minimize, and/or otherwise reduce the amount of dishing that occurs in the top surface of the through-substrate interconnect structure during planarization of the through-substrate interconnect structure. The dielectric insert(s) are formed of a dielectric material having a hardness that is greater than the hardness of the metal material of the through-substrate interconnect structure. The greater hardness enables the dielectric insert(s) to resist material removal during planarization of the through-substrate interconnect structure, which enables a high uniformity in the material removal rates across the top surface of the through-substrate interconnect structure to be achieved. The reduced amount of dishing during planarization of the through-substrate interconnect structure reduces the likelihood of removal of liner material from one or more liners between the sidewalls of the through-substrate interconnect structure and the substrate layer.

### BACKGROUND

Various semiconductor device packing techniques may be used to incorporate one or more semiconductor dies into a semiconductor die package. In some cases, semiconductor dies may be horizontally interconnected through an interposer. Additionally and/or alternatively, semiconductor dies may be arranged vertically in a semiconductor die package to achieve a smaller horizontal or lateral footprint of the semiconductor die package and/or to increase the density of the semiconductor die package. The semiconductor dies may be connected directly through die-to-die (or wafer-to-wafer) bonding and/or through interconnects and one or more interposers.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example semiconductor package described herein.

FIGS. 2A and 2B are diagrams of example implementations of a through-substrate interconnect structure in a semiconductor die described herein.

FIGS. 3A-3K are diagrams of an example implementation of forming a semiconductor die described herein.

FIGS. 4A-4D are diagrams of an example implementation of forming a semiconductor package described herein.

FIGS. 5A-5E are diagram of example implementations of top view layouts for dielectric inserts in a through-substrate interconnect structure described herein.

FIG. 6 is a flowchart of an example process associated with forming a semiconductor device described herein.

FIG. 7 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A semiconductor die in a semiconductor package may be connected to interconnect layers on both sides of the semiconductor die. For example, a first interconnect layer may be included on a first side (e.g., a front side) of the semiconductor die, and a second interconnect layer may be included on a second side (e.g., a back side) of the semiconductor die opposing the first side. In some cases, the first interconnect layer may be used for routing signals throughout the semiconductor die, and the second interconnect layer may be used for providing power to the integrated circuit devices of the semiconductor die. Additionally and/or alternatively, one of the first or second interconnect layers may be bonded to another semiconductor die and may be used for inter-die communication, and the other interconnect layer may be connected to the connector of the semiconductor package for making external connections.

To enable signals and/or power to be routed between the first and second interconnect layers, one or more through-substrate interconnect structures may be included through a substrate layer (e.g., a device layer or semiconductor layer) in which the integrated circuit devices are included. The through-substrate interconnect structure(s) (sometimes referred to as through-silicon vias or through-substrate vias (TSVs)) connect with one or more metallization layers in the first and second interconnect layers, and may be formed of electrically conductive metals such as copper (Cu) to achieve a low electrical resistance between the metallization layers in the first and second interconnect layers through the elongated conductive structure(s).

A through-substrate interconnect structure may be formed by forming a recess in and/or through the substrate layer, filling the recess with electrically conductive material, and then planarizing the through-substrate interconnect structure to remove excess electrically conductive material. The planarization operation may result in dishing in the top surface of the through-substrate interconnect structure. Dishing refers to a concave profile that results in the top surface due to non-uniform removal of electrically conductive material from the through-substrate interconnect structure. In some cases, dishing may also result in removal of liner material from one or more liners between the sidewalls of the through-substrate interconnect structure and the substrate layer, and current leakage can occur into the substrate layer through these areas where the liner material was removed due to dishing.

In some implementations described herein, one or more dielectric inserts are formed in a through-substrate interconnect structure to prevent, minimize, and/or otherwise reduce the amount of dishing that occurs in the top surface of the through-substrate interconnect structure during planarization of the through-substrate interconnect structure. The dielectric insert(s) are formed of a dielectric material having a hardness that is greater than the hardness of the metal material of the through-substrate interconnect structure. The greater hardness enables the dielectric insert(s) to resist material removal during planarization of the through-substrate interconnect structure, which enables a high uniformity in the material removal rates across the top surface of the through-substrate interconnect structure to be achieved. The reduced amount of dishing during planarization of the through-substrate interconnect structure reduces the likelihood of removal of liner material from one or more liners between the sidewalls of the through-substrate interconnect structure and the substrate layer. In this way, the dielectric insert(s) reduce the likelihood of current leakage from the through-substrate interconnect structure into the substrate layer.

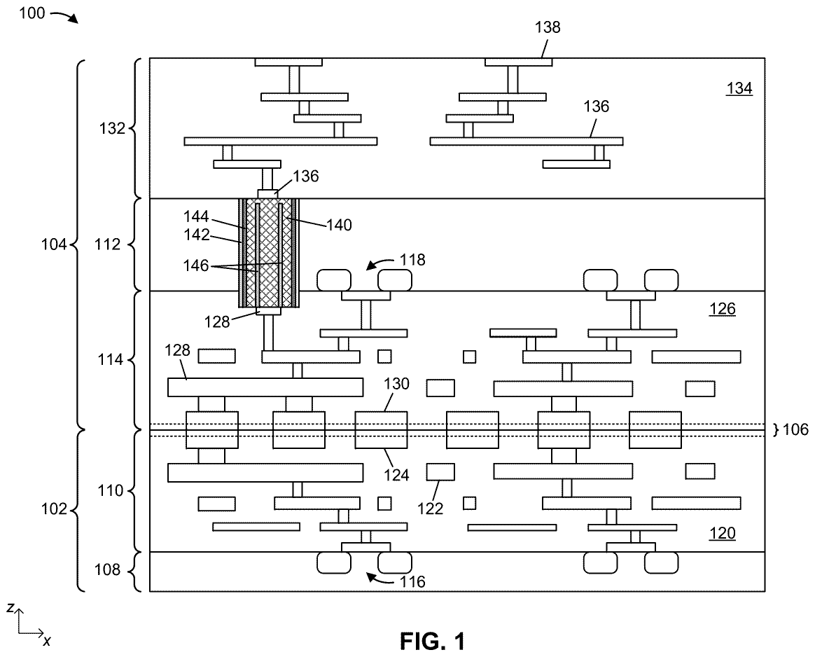

FIG. 1 is a diagram of an example semiconductor package 100 described herein. FIG. 1 illustrates a cross-section view of the semiconductor package 100. As shown in FIG. 1, the semiconductor package 100 includes a semiconductor die 102 and a semiconductor die 104 bonded at a bonding interface 106 such that the semiconductor dies 102 and 104 are stacked and vertically arranged (e.g., in a z-direction) in the semiconductor package 100. The bond between the semiconductor dies 102 and 104 may be formed by bonding semiconductor wafers together (e.g., wafer-to-wafer bonding), by bonding dies together (die-to-die bonding), and/or by bonding a die to a wafer (e.g., die-to-wafer bonding), among other example bonding configurations. A bonding tool may be used to perform a bonding operation to bond the semiconductor dies 102 and 104 by forming metal-to-metal bonds and/or dielectric-to-dielectric bonds at the bonding interface 106 between the semiconductor dies 102 and 104.

The semiconductor die 102 may include a system on chip (SoC) die, such as a logic die, a central processing unit (CPU) die, a graphics processing unit (GPU) die, a digital signal processing (DSP) die, an application specific integrated circuit (ASIC) die, and/or another type of SoC die. Additionally and/or alternatively, the semiconductor die 102 may include a memory die, an input/output (I/O) die, a pixel sensor die, and/or another type of semiconductor die. A memory die may include a static random access memory (SRAM) die, a dynamic random access memory (DRAM) die, a NAND die, a high bandwidth memory (HBM) die, and/or another type of memory die. The semiconductor die 104 may include the same type of semiconductor die as the semiconductor die 102, or may include a different type of semiconductor die.

As further shown in FIG. 1, the semiconductor die 102 may include a device layer 108 and an interconnect layer 110 above the device layer 108. The semiconductor die 104 may include a device layer 112 and an interconnect layer 114 below the device layer 112. The bonding interface 106 may be located between the interconnect layers 110 and 114, and may include portions of each of the interconnect layers 110 and 114. The bonding interface 106 may include conductive structures of the interconnect layers 110 and 114 that are bonded together by metal-to-metal bonds, and/or dielectric layers of the interconnect layers 110 and 114 that are bonded together by dielectric-to-dielectric bonds.

The device layer 108 may correspond to a portion of a semiconductor wafer on which the semiconductor die 102 was formed. Therefore, the device layer 108 may be referred to as the substrate layer of the semiconductor die 102. The device layer 112 may correspond to a portion of another semiconductor wafer on which the semiconductor die 104 was formed. Therefore, the device layer 112 may be referred to as the substrate layer of the semiconductor die 104. The device layers 108 and 112 may each include a silicon (Si) substrate, a substrate formed of a material including silicon, a III-V compound semiconductor material substrate such as gallium arsenide (GaAs), a silicon on insulator (SOI) substrate, or another type of semiconductor substrate.

The device layers 108 and 112 may respectively include integrated circuit devices 116 and 118 of the semiconductor dies 102 and 104. The integrated circuit devices 116 and 118 may each include transistors (e.g., planar transistors, fin field effect transistors (finFETs), gate all around (GAA) transistors), pixel sensors, capacitors, resistors, inductors, photodetectors, transceivers, transmitters, receives, optical circuits, and/or other types of passive and/or active integrated circuit devices.

The interconnect layers 110 and 114 may each include conductive structures that interconnect the integrated circuit devices 116 and 118 of the device layers 108 and 112, respectively. Additionally and/or alternatively, the interconnect layers 110 and 114 may each include conductive structures that electrically connect the semiconductor dies 102 and 104.

The interconnect layer 110 of the semiconductor die 102 includes one or more dielectric layers 120 that are arranged in a direction that is approximately perpendicular to the device layer 108. The dielectric layer(s) 120 may include backend dielectric layers (e.g., interlayer dielectric (ILD) layers, intermetal dielectric (IMD) layers) and etch stop layers (ESLs) that are arranged in an alternating manner in the interconnect layer 110. The dielectric layer(s) 120 may each include an oxide (e.g., a silicon oxide (SiOₓ) and/or another oxide material), an undoped silicate glass (USG), a boron-containing silicate glass (BSG), a fluorine-containing silicate glass (FSG), an extreme low dielectric constant (ELK) dielectric material having a dielectric constant that is less than approximately 2.5, a silicon nitride (SiₓN_{y}), silicon carbide (SiC), silicon oxynitride (SiON), and/or another suitable dielectric material.

The interconnect layer 110 includes a plurality of conductive structures 122 (e.g., electrically conductive structures) in the dielectric layer(s) 120. The conductive structures 122 are electrically coupled and/or physically coupled with one or more of the integrated circuit devices 116 in the device layer 108, and are electrically interconnected together in the interconnect layer 110. The conductive structures 122 correspond to circuit routing that enables signals and/or power to be provided to and/or from the integrated circuit devices 116. The conductive structures 122 may include a combination of conductive structures that extend primarily horizontally (e.g., in an x-direction and/or in a y-direction) in the interconnect layer 110 (e.g., trenches, conductive lines) and that are interconnected by interconnect structures (e.g., vias) that extend primarily vertically (e.g., in the z-direction) in the interconnect layer 110. The conductive structures 122 may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

The conductive interconnects of the interconnect layer 110 may be arranged in a vertical manner (e.g., in the z-direction) to facilitate electrical signals and/or power to be routed between the device layer 108 and the semiconductor die 104, between integrated circuit devices 116 through the interconnect layer 110, and/or between the integrated circuit devices 116 and the integrated circuit devices 118 in the semiconductor die 104. The conductive structures 122 may be arranged in alternating layers of metallization layers (referred to as “M” layers) and via layers (referred to as “V” layers). Each metallization layer may include one or more conductive structures laterally arranged in the interconnect layer 110, and each via layer may include one or more interconnect structures that interconnect the metallization layers in the interconnect layer 110. As an example, a metal-0 (M0) layer may be located at the bottom of the interconnect layer 110 and may be coupled with the integrated circuit devices 116 in the device layer 108, a via-0 (V0) layer may be located above and coupled with the M0 layer in the interconnect layer 110, a metal-1 (M1) layer may be located above and coupled with the V0 layer in the interconnect layer 110, a via-1 (V1) layer may be located above and coupled with the M1 layer in the interconnect layer 110, a metal-2 (M2) layer may be located above and electrically coupled with the V1 layer in the interconnect layer 110, and so on. In some implementations, the interconnect layer 110 includes nine (9) stacked metallization layers (e.g., M0-M8). In other implementations, the contact layer (referred to as “CO” layer) may be located at the bottom of the interconnect layer 110 and may be coupled with the integrated circuit devices 116 in the device layer 108, a metal-1 (M1) layer may be located above and coupled with the CO layer in the interconnect layer 110, and so on. In some implementations, the interconnect layer 110 includes another quantity of stacked metallization layers.

At the bonding interface 106, the interconnect layer 110 may include a plurality of bonding pads 124. The bonding pads 124 may be electrically coupled with the conductive structures 122 in the interconnect layer 110 by bonding vias and/or other types of conductive structures. The bonding pads 124 may each include tungsten (W), cobalt (Co), ruthenium (Ru), titanium (Ti), aluminum (Al), copper (Cu), gold (Au), and/or a combination thereof, among other examples of electrically conductive metals.

As further shown in FIG. 1, the interconnect layer 114 of the semiconductor die 104 may include a similar combination and/or arrangement of structures and/or layers as the interconnect layer 110 of the semiconductor die 102. For example, the semiconductor die 104 may include a combination of one or more dielectric layers 126 and conductive structures 128 in the dielectric layer(s) 126. Moreover, the interconnect layer 114 may include bonding pads 130 that are electrically coupled with one or more of the conductive structures 128 (e.g., by bonding vias and/or other types of conductive structures). These layers and/or structures may have a reversed vertical arrangement relative to the semiconductor die 102, which enables the semiconductor die 102 and the semiconductor die 104 to be bonded at the bonding interface 106 such that the interconnect layer 110 and the interconnect layer 114 are facing each other.

At the bonding interface 106, the bonding pads 124 of the semiconductor die 102 and the bonding pads 130 of the semiconductor die 104 are directly bonded by metal-to-metal bonds. Moreover, a dielectric layer of the one or more dielectric layers 120 of the semiconductor die 102 and a dielectric layer of the one or more dielectric layers 126 of the semiconductor die 104 are directly bonded by dielectric-to-dielectric bonds.

As further shown in FIG. 1, the semiconductor die 104 may include another interconnect layer 132. The interconnect layer 114 may be located on a first side (e.g., a front side) of the device layer 112 of the semiconductor die 104, and the interconnect layer 132 may be located on a second side (e.g., a back side) of the device layer 112 opposing the first side. The interconnect layer 114 may be configured to route signals and/or power between the semiconductor dies 102 and 104, and/or may be configured to route signals and/or power between integrated circuit devices 118 of the semiconductor die 104. The interconnect layer 132 may be configured to route signals and/or power between the semiconductor die 104 and devices external to the semiconductor package 100. For example, the interconnect layer 132 may be configured to route signals and/or power between the semiconductor die 104 and an external high bandwidth memory (HBM) die, an external system on chip (SoC) die, an external input/output (I/O) die, and/or another type of device external to the semiconductor package 100.

The interconnect layer 132 of the semiconductor die 104 includes one or more dielectric layers 134 (e.g., ILD layers, IMD layers, ESLs) and conductive structures 136 (e.g., trenches, metallization layers, vias, interconnect structures) in the dielectric layer(s) 134. The dielectric layer(s) 134 may each include an oxide (e.g., a silicon oxide (SiOₓ) and/or another oxide material), a USG, a BSG, an FSG, an ELK dielectric material, a silicon nitride (SiₓN_{y}), silicon carbide (SiC), silicon oxynitride (SiON), and/or another suitable dielectric material. The conductive structures 136 may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

The interconnect layer 132 further includes connection structures 138 that enable the semiconductor package 100 to be attached to a substrate (e.g., an interposer, a printed circuit board (PCB)), another semiconductor die package, and/or to be attached to another structure.

The connection structures 138 may include bonding pads and/or another type of connection structures.

As further shown in FIG. 1, the semiconductor package 100 includes one or more through-substrate interconnect structures 140 that extend through the device layer 112 (e.g., the substrate layer) of the semiconductor die 104. A through-substrate interconnect structure 140 may extend into the interconnect layer 114 and may be physically coupled and/or electrically coupled with a conductive structure 128 (e.g., a metal pad) in the interconnect layer 114 at a first end, and that is physically coupled and/or electrically coupled with a conductive structure 136 (e.g., a metal pad) in the interconnect layer 132 at a second end vertically opposing (e.g., in the z-direction) the first end. A through-substrate interconnect structure 140 may include a via, a metal pillar, a metal column, and/or other another type of vertically elongated (e.g., elongated in the z-direction) conductive structure. A through-substrate interconnect structure 140 may be referred to as a TSV structure in that the through-substrate interconnect structure 140 extends fully through a semiconductor layer (e.g., a silicon substrate) of the device layer 112. The second end of the through-substrate interconnect structure 140 (e.g., the second end) may be approximately co-planar with the bottom of the device layer 112.

A through-substrate interconnect structure 140 may include one or more electrically conductive materials (e.g., electrically conductive metals), such as copper (Cu), gold (Au), silver (Ag), nickel (Ni), tin (Sn), ruthenium (Ru), cobalt (Co), tungsten (W), titanium (Ti), one or more metals, one or more conductive ceramics, and/or another type of conductive material. The electrically conductive material of the through-substrate interconnect structure 140 may be susceptible to diffusion and/or current leakage into the substrate layer of the device layer 112.

Accordingly, one or more liners may be included between the through-substrate interconnect structure 140 and the substrate layer of the device layer 112 to provide a diffusion barrier and/or to provide electrical isolation between the through-substrate interconnect structure 140 and the substrate layer.

The one or more liners include a liner 142 between the substrate layer of the device layer 112 and the through-substrate interconnect structure 140, and/or a liner 144 between the liner 142 and the through-substrate interconnect structure 140, among other examples. In some implementations, the liners 142, 144 may each include one or more dielectric materials. In some implementations, the liner 142 and the liner 144 may include the same material or the same material composition. In some implementations, the liner 142 and the liner 144 may include different materials and/or different material compositions.

The liners 142, 144 may each include one or more low dielectric constant (low-k) dielectric materials (e.g., dielectric materials having a dielectric constant of approximately 3.9 or less) and/or one or more high dielectric constant (high-k) dielectric materials (e.g., dielectric materials having a dielectric constant of greater than approximately 3.9). Examples of such high-k dielectric materials include a silicon nitride (SiₓN_{y} such as Si₃N₄), an aluminum oxide (AlₓO_{y} such as Al₂O₃), a tantalum oxide (TaₓO_{y} such as Ta₂O₅), a titanium oxide (TiOₓ such as TiO₂), a zirconium oxide (ZrOₓ such as ZrO₂), a hafnium oxide (HfOₓ such as HfO₂), a strontium titanium oxide (SrTiOₓ such as SrTiO₃), hafnium silicon oxide (HfSiOₓ such as HfSiO₄), lanthanum oxide (LaₓO_{y} such as La₂O₃), yttrium oxide (YₓO_{y} such as Y₂O₃), and/or amorphous lanthanum aluminum oxide (a-LaAlOₓ such as a-LaAlO₃), among other examples. In some implementations, the liner 142 and/or the liner 144 includes a multiple-layer thin film, where each layer includes a different high-k dielectric material. Examples of low dielectric materials for the liners 142 and/or 144 include a silicon oxide (SiOₓ such as SiO₂), an undoped silicate glass (USG), a boron-containing silicate glass (BSG), and/or a fluorine-containing silicate glass (FSG), among other examples.

As further shown in FIG. 1, one or more dielectric inserts 146 are included in a through-substrate interconnect structure 140 of the semiconductor die 104. The dielectric insert(s) 146 may be vertically elongated (e.g., in the z-direction) and may extend into and/or through the through-substrate interconnect structure 140 in the z-direction. The dielectric insert(s) 146 may include dielectric pillar(s), dielectric ring(s), dielectric column(s), dielectric plug(s), that are contained within a perimeter of the through-substrate interconnect structure 140. The dielectric insert(s) 146 may be included to achieve a greater planarization uniformity when planarizing the first end of the through-substrate interconnect structure 140 by reducing the amount of dishing that occurs in the first end of the through-substrate interconnect structure 140 from the planarization. While two dielectric inserts 146 are shown in the examples in the figures, other quantities of dielectric inserts 146 that may be included in a through-substrate interconnect structure 140 are within the scope of the present disclosure.

The dielectric material of the dielectric insert(s) 146 have a greater hardness than the electrically conductive material of the through-substrate interconnect structure 140, and therefore the dielectric insert(s) 146 have a higher resistance to material removal than the through-substrate interconnect structure 140. For example, the dielectric insert(s) 146 may include a silicon oxide (SiOₓ such as SiO₂) and the through-substrate interconnect structure 140 may include copper (Cu). Other examples of materials for the dielectric insert(s) 146 include silicon carbide (SiC), silicon oxynitride (SiON), silicon oxycarbonitride (SiOCN), and/or a silicon nitride (SiₓN_{y} such as Si₃N₄), among other examples.

When planarizing the through-substrate interconnect structure 140, the softer material of the through-substrate interconnect structure 140 may allow a planarization pad of a planarization tool may deform across the surface of the first end of the through-substrate interconnect structure 140, resulting in the surface of the first end of the through-substrate interconnect structure 140 becoming concave. The harder material of the dielectric insert(s) 146 inhibits deformation of the planarization pad across the surface of the first end of the through-substrate interconnect structure 140, thereby preventing the first end of the through-substrate interconnect structure 140 from becoming concave (or thereby minimizing and/or otherwise reducing the depth of the concavity of the first end of the through-substrate interconnect structure 140). This prevents, minimizes, and/or otherwise reduces the likelihood of the liners 142, 144 from being removed from the substrate layer of the device layer 112, which prevents, minimizes, and/or otherwise reduces the likelihood of current leakage and/or material migration from the through-substrate interconnect structure 140 into the substrate layer of the device layer 112 of the semiconductor die 104.

As indicated above, FIG. 1 is provided as an example. Other examples may differ from what is described with regard to FIG. 1.

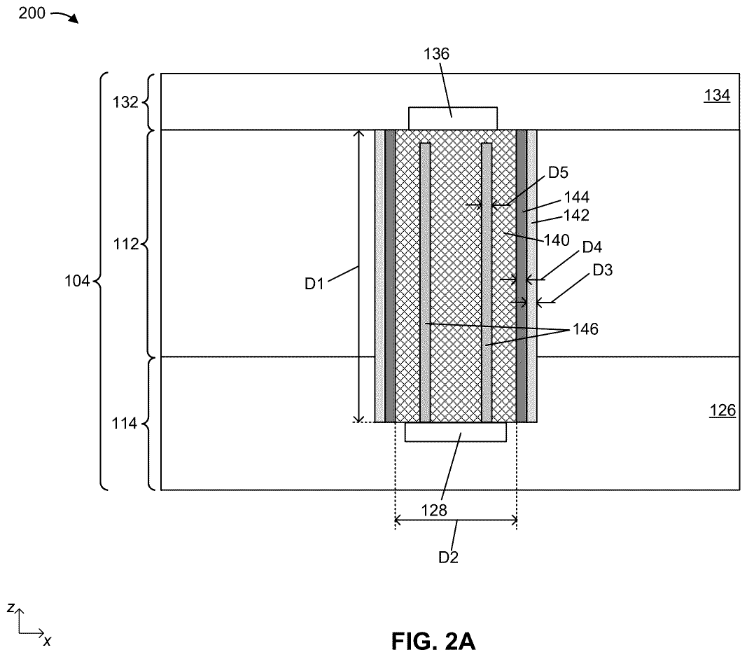

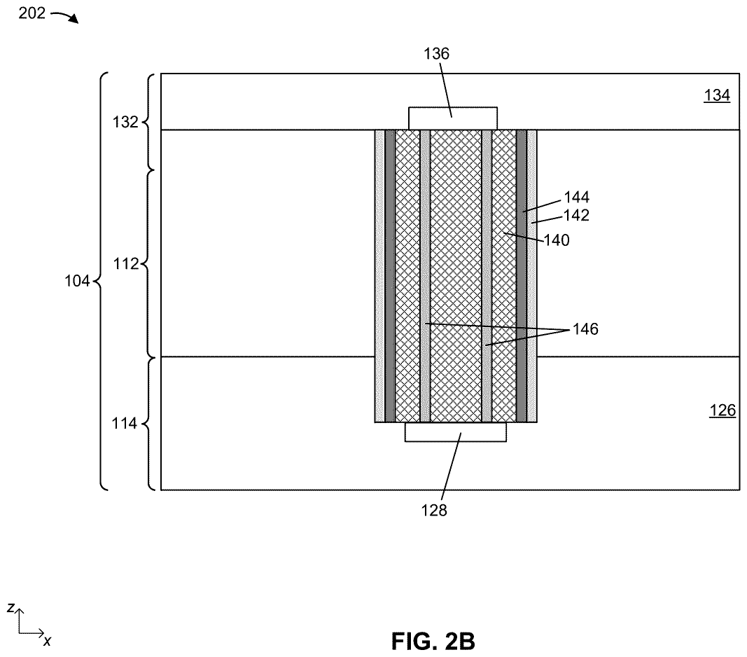

FIGS. 2A and 2B are diagrams of an example implementations of a through-substrate interconnect structure 140 in the semiconductor die 104 described herein. The example implementations of through-substrate interconnect structure 140 illustrated in FIGS. 2A and 2B include one or more dielectric inserts 146 that are included to prevent, minimize, and/or otherwise reduce the likelihood of and/or the amount of dishing that occurs in one or more ends of the through-substrate interconnect structure 140.

As shown in FIG. 2A, an example implementation 200 of a through-substrate interconnect structure 140 includes one or more dielectric inserts 146 that are located within a perimeter of the through-substrate interconnect structure 140 an extend into the through-substrate interconnect structure 140 in the z-direction. The dielectric insert(s) 146 may extend into the through-substrate interconnect structure 140 from the first end of the through-substrate interconnect structure 140 in the interconnect layer 114, and may terminate within the through-substrate interconnect structure 140 such that a bottom portion of the through-substrate interconnect structure 140 is included between the dielectric insert(s) 146 and the interconnect layer 132. Thus, first ends of the dielectric insert(s) 146 may be approximately co-planar with the first end of the through-substrate interconnect structure 140, and second (opposing) ends of the dielectric insert(s) 146 may terminate in the through-substrate interconnect structure 140 at a depth that is less than the full depth of the through-substrate interconnect structure 140.

As further shown in FIG. 2A, the example implementation 200 of the through-substrate interconnect structure 140 may have one or more example dimensions. An example dimension D1 corresponds to a vertical (z-direction) height of the through-substrate interconnect structure 140. In some implementations, the vertical height of the through-substrate interconnect structure 140 may be included in a range of approximately 10 microns to approximately 100 microns. However, other values and ranges are within the scope of the present disclosure.

Another example dimension D2 corresponds to a lateral width (e.g., an x-direction width, a y-direction width) of the through-substrate interconnect structure 140. In some implementations, the lateral width of the through-substrate interconnect structure 140 may be included in a range of approximately 1 micron to approximately 10 microns. However, other values and ranges are within the scope of the present disclosure.

The through-substrate interconnect structure 140 may have a high aspect ratio (e.g., a ratio of the height to the top width (e.g., D1:D2)). For example, the aspect ratio of the through-substrate interconnect structure 140 may be included in a range of approximately 5:1 to approximately 15:1. However, other values and ranges are within the scope of the present disclosure.

Another example dimension D3 includes a lateral thickness (x-direction thickness, y-direction thickness) of the liner 142 on the sidewalls of the through-substrate interconnect structure 140. In some implementations, the lateral thickness of the liner 142 is included in a range of approximately 1000 angstroms to approximately 2000 angstroms. However, other values and ranges are within the scope of the present disclosure.

Another example dimension D4 includes a lateral thickness (x-direction thickness, y-direction thickness) of the liner 144 on the sidewalls of the through-substrate interconnect structure 140. In some implementations, the lateral thickness of the liner 144 is included in a range of approximately 1000 angstroms to approximately 3000 angstroms. However, other values and ranges are within the scope of the present disclosure.

Another example dimension D5 includes a lateral thickness (x-direction thickness, y-direction thickness) of a dielectric insert 146 in the through-substrate interconnect structure 140. In some implementations, the lateral thickness of a dielectric insert 146 is included in a range of approximately 10 angstroms to approximately 1000 angstroms. Thus, the lateral thickness of a dielectric insert 146 may be less than the lateral thickness of the liner 142 (e.g., D3>D5), and/or the lateral thickness of a dielectric insert 146 may be less than the lateral thickness of the liner 144 (e.g., D4>D5). If the lateral thickness of the dielectric insert 146 is less than approximately 10 angstroms, the dielectric insert 146 may not sufficiently inhibit dishing in the first end and/or in the second end of the through-substrate interconnect structure 140. If the lateral thickness of the dielectric insert 146 is greater than approximately 1000 angstroms, the electrical resistance of the through-substrate interconnect structure 140 may be higher because the recess in which the through-substrate interconnect structure 140 is formed is filled with a greater amount of dielectric material which provides less area for the electrically conductive material of the through-substrate interconnect structure 140. Moreover, the gap-filling performance (e.g., the copper electroplating performance) for the through-substrate interconnect structure 140 may be reduced. However, other values, and ranges other than approximately 10 angstroms to approximately 100 angstroms are within the scope of the present disclosure.

As shown in FIG. 2B, another example implementation 202 of a through-substrate interconnect structure 140 is similar to the example implementation 200, except that the dielectric insert(s) 146 in the example implementation 202 extend fully through the through-substrate interconnect structure 140. In other words, the dielectric insert(s) 146 extend continuously and fully between the first end of the through-substrate interconnect structure 140 (e.g., that is coupled to a conductive structure 128 in the interconnect layer 114) and the second end of the through-substrate interconnect structure 140 (e.g., that is coupled to a conductive structure 136 in the interconnect layer 132). In the example implementation 202, the back side of the substrate layer of the device layer 112 is planarized (e.g., using a wafer grinding tool to perform a wafer grinding operation) until the dielectric insert(s) 146 are reached. Thus, the dielectric insert(s) 146 prevent, minimize, and/or otherwise reduce the likelihood of dishing in the first end of the through-substrate interconnect structure 140 (e.g., during front side processing of the semiconductor die 104) as well as in the second end of the through-substrate interconnect structure 140 (e.g., during back side processing of the semiconductor die 104).

As indicated above, FIGS. 2A and 2B are provided as examples. Other examples may differ from what is described with regard to FIGS. 2A and 2B.

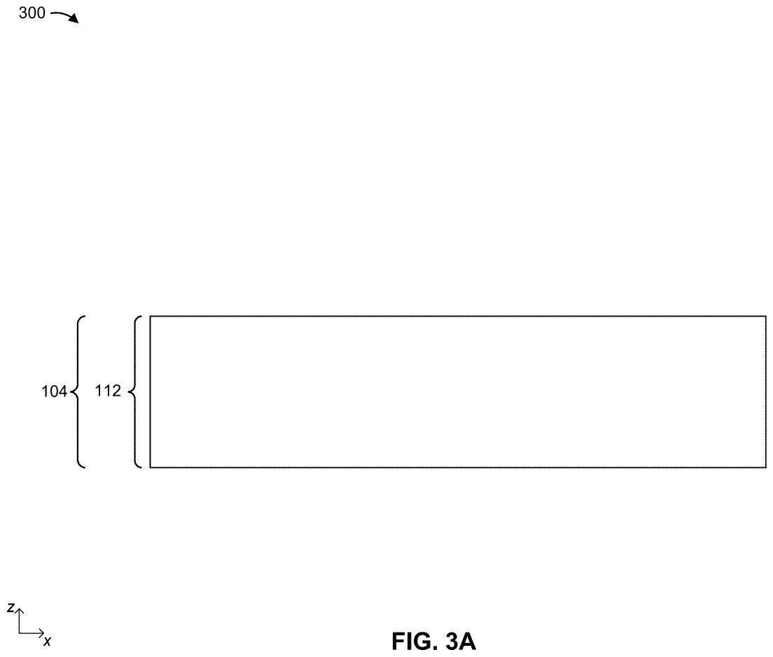

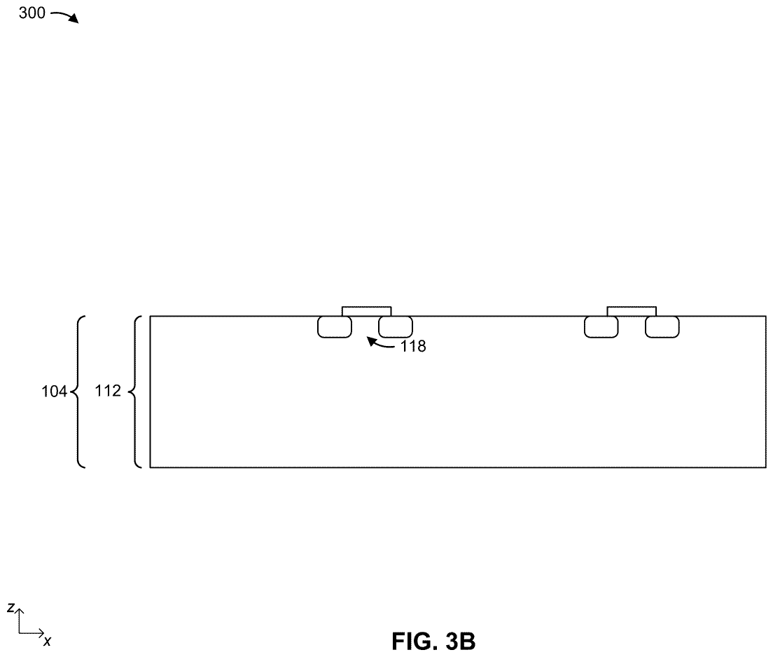

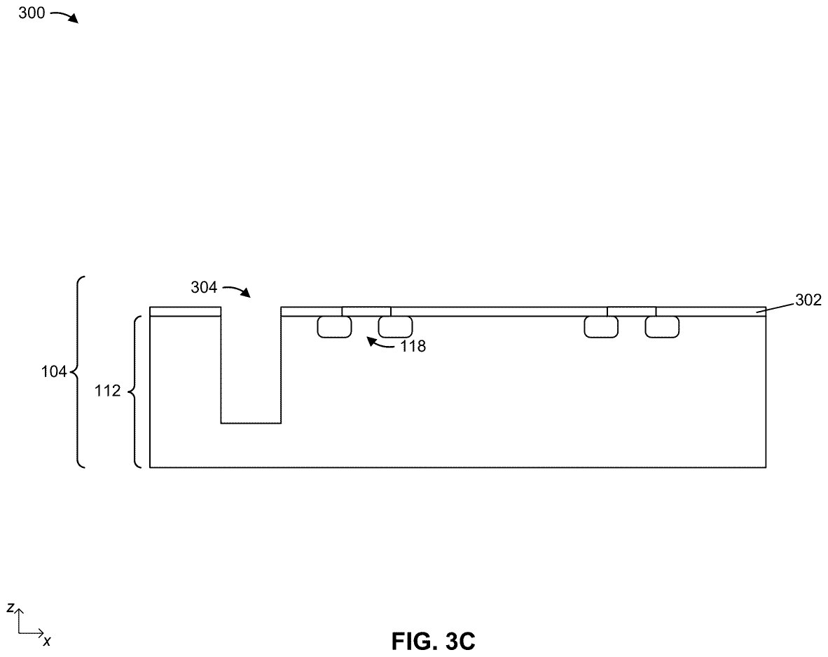

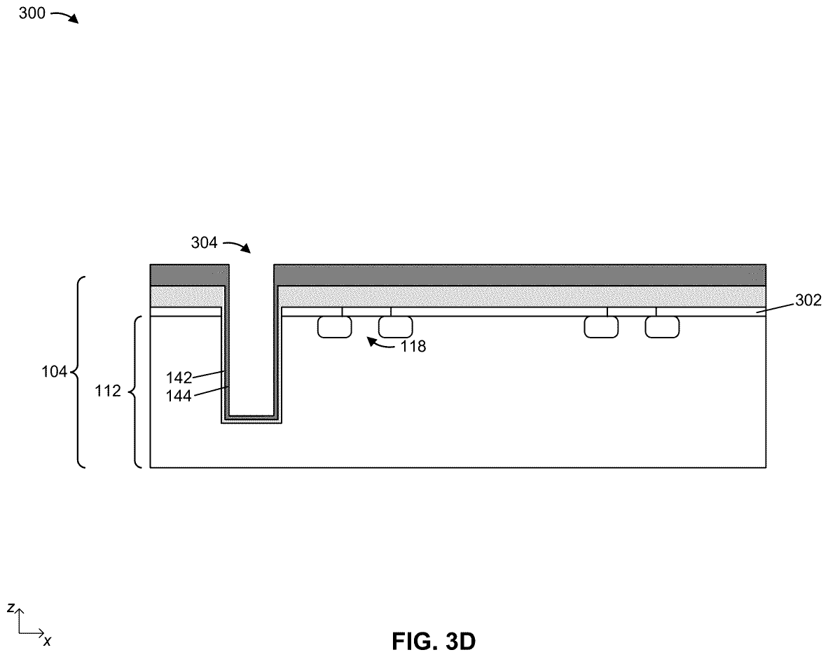

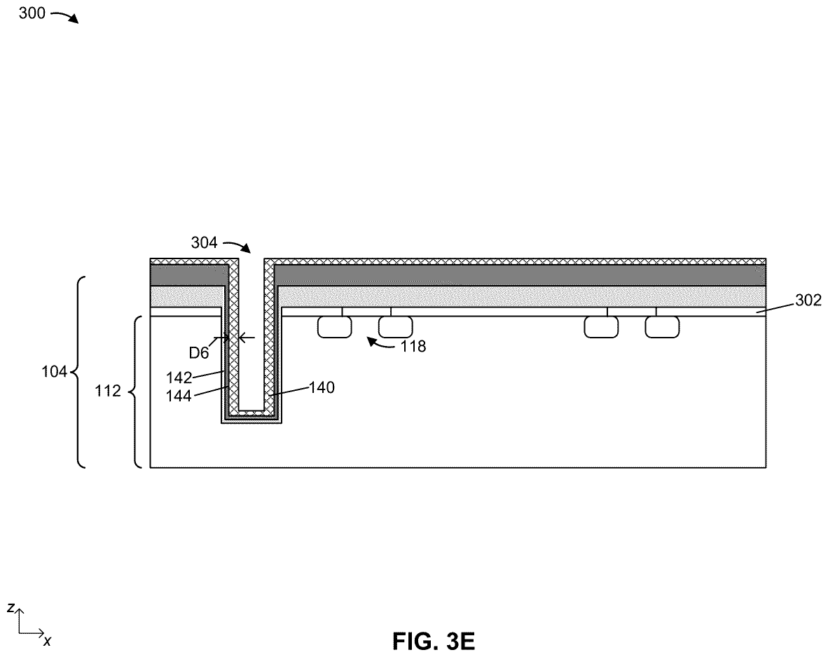

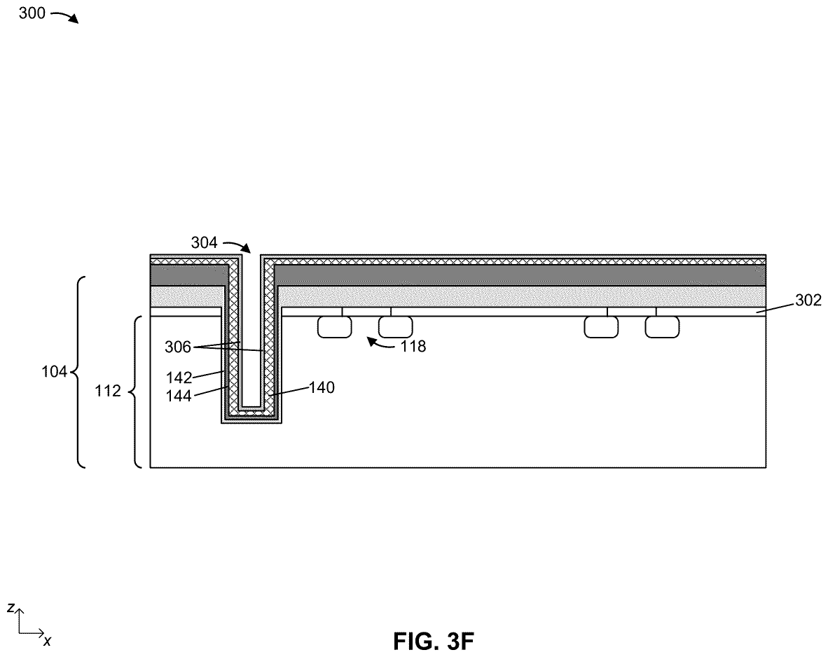

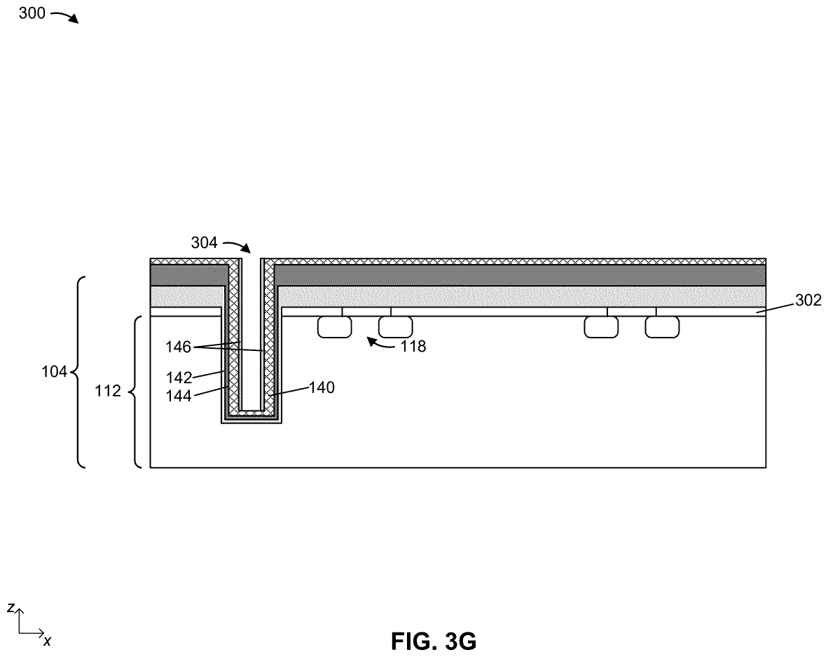

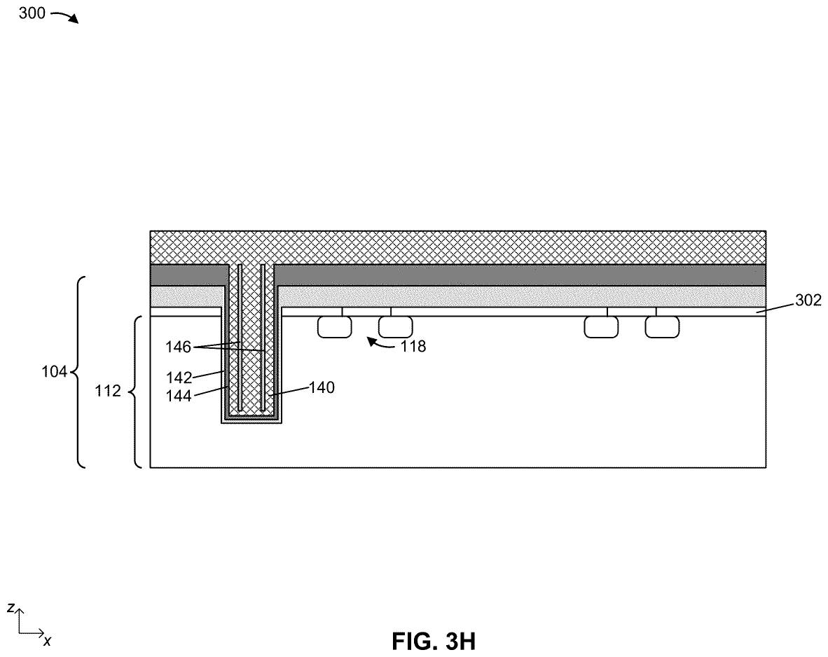

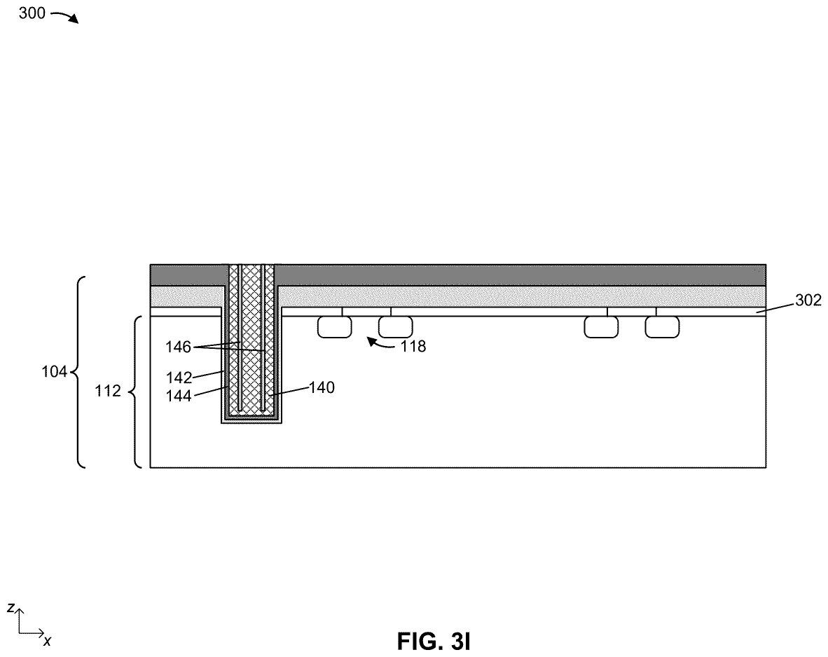

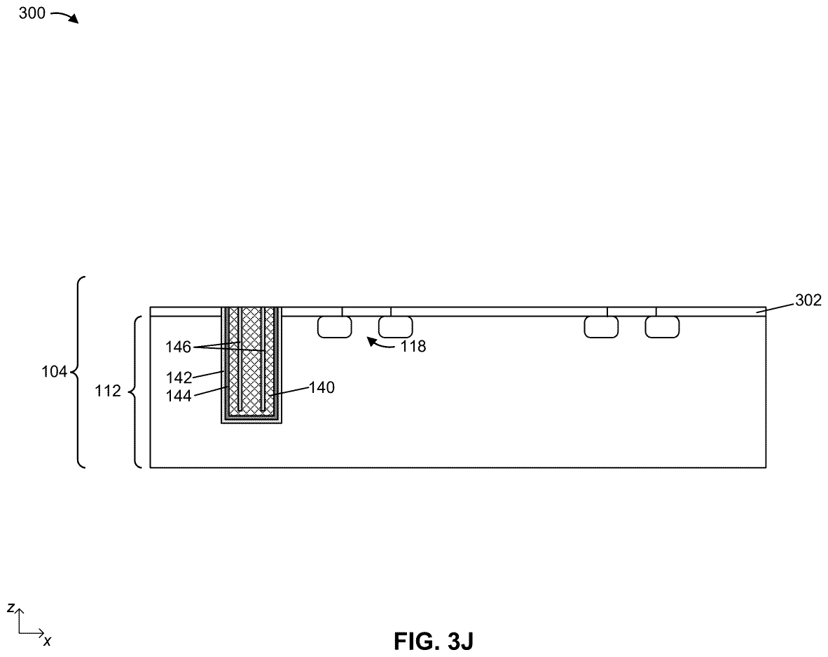

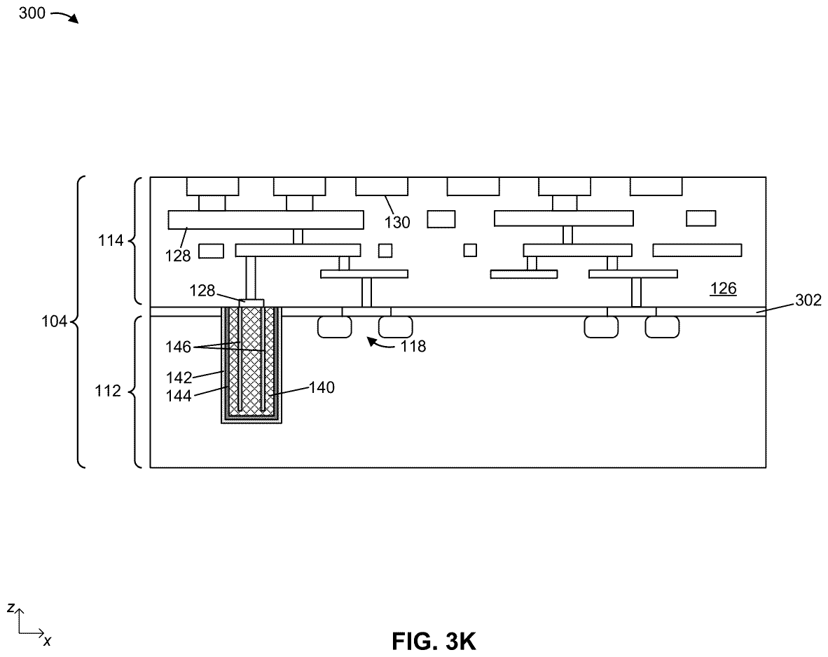

FIGS. 3A-3K are diagrams of an example implementation 300 of forming a semiconductor die described herein. In some implementations, the example implementation 300 includes an example process for forming the semiconductor die 104 or a portion thereof. In some implementations, one or more semiconductor processing tools may be used to perform one or more of the operations described in connection with the example implementation 300, such as a deposition tool, an exposure tool, a developer tool, an etch tool, a planarization tool, a plating tool, and/or another type of semiconductor processing tool.

Turning to FIG. 3A, one or more of the operations in the example implementation 300 may be performed in connection with the semiconductor layer of the device layer 112 of the semiconductor die 104. The semiconductor layer of the device layer 112 may be provided in the form of a semiconductor wafer or another type of substrate layer.

As shown in FIG. 3B, the integrated circuit devices 118 may be formed in and/or on the device layer 112 of the semiconductor die 104. One or more semiconductor processing tools may be used to form one or more portions of the integrated circuit devices 118. For example, a deposition tool may be used to perform various deposition operations to deposit layers of the integrated circuit devices 118, and/or to deposit photoresist layers for etching the semiconductor layer of the device layer 112 and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the semiconductor layer and/or portions of the deposited layers to form the integrated circuit devices 118. As another example, a planarization tool may be used to planarize portions of the integrated circuit devices 118. As another example, an ion implantation tool may be used to implant ions in the semiconductor layer to dope portions of the semiconductor layer of the device layer 112 with one or more types of dopants (e.g., p-type dopants, n-type dopants).

As shown in FIG. 3C, a hard mask layer 302 may be formed over and/or on the front side of the substrate layer of the device layer 112. The hard mask layer 302 may include a dielectric material such as silicon carbide (SiC), silicon nitride (SiₓN_{y}), silicon oxide (SiOₓ), and/or another suitable dielectric material. In some implementations, the hard mask layer 302 is formed to a thickness that is included in a range of approximately 500 angstroms to approximately 600 angstroms. However, other values and ranges are within the scope of the present disclosure.

A deposition tool may be used to deposit the hard mask layer 302 using a physical vapor deposition (PVD) technique, an atomic layer deposition (ALD) technique, a chemical vapor deposition (CVD) technique, an oxidation technique, and/or another suitable deposition technique. In some implementations, a planarization tool may be used to perform a planarization operation (e.g., a chemical-mechanical planarization (CMP) operation) to planarize the hard mask layer 302 after the hard mask layer 302 is deposited.

As further shown in FIG. 3C, a recess 304 may be formed through the hard mask layer 302 and into a portion of the substrate layer of the device layer 112. In some implementations, a pattern is formed in a photoresist layer and then transferred to the hard mask layer 302, and the pattern in the hard mask layer 302 is used to etch the substrate layer of the device layer 112 to form the recess 304. In these implementations, a deposition tool may be used to form the photoresist layer on the hard mask layer 302 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the hard mask layer 302 based on the pattern to transfer the pattern to the hard mask layer 302, and an etch tool may be used to etch the substrate layer of the device layer 112 based on the pattern in the hard mask layer 302 to form the recess 304. In some implementations, the hard mask layer 302 and/or the substrate layer of the device layer 112 may be etched using a dry etch technique (e.g., a plasma-based etch technique, a gas-based etch technique), a wet chemical etch technique, and/or another type of etch technique. In some implementations, a photoresist removal tool may be used to remove the remaining portions of the photoresist layer (e.g., using a chemical stripper, plasma ashing, and/or another technique).

As shown in FIG. 3D, the liner 142 may be conformally deposited on the sidewalls and on the bottom surface of the recess 304. Moreover, the liner 144 may be conformally deposited on the liner 142 such that the liner 144 is formed on the sidewalls and on the bottom surface of the recess 304. A deposition tool may be used to deposit the liners 142 and/or 144 using an ALD technique, a CVD technique, an electroplating technique, and/or another suitable deposition technique. The material of the liners 142 and/or 144 may also deposited along the top surface of the hard mask layer 302, as shown in the example in FIG. 3D.

As shown in FIG. 3E, a first portion of a through-substrate interconnect structure 140 is formed in the recess 304. The first portion of the through-substrate interconnect structure 140 may include a layer of electrically conductive material that is formed on the liners 142 and/or 144. The first portion of the through-substrate interconnect structure 140 may be formed on the sidewalls and on the bottom surface of the recess 304. In some implementations, the first portion of the through-substrate interconnect structure 140 is formed using a deposition tool to by forming a layer of electroplated copper on the sidewalls on the bottom surface of the recess 304. In some implementations, the first portion of the through-substrate interconnect structure 140 is formed using another deposition technique.

The first portion of the through-substrate interconnect structure 140 may be formed to a thickness (indicated in FIG. 3E as a dimension D6) that is included in a range of approximately 0.5 microns to approximately 5 microns. The thickness first portion of the through-substrate interconnect structure 140 may be used to define the spacing between the sidewalls of the through-substrate interconnect structure 140 and the dielectric insert(s) 146 that are to be formed in the through-substrate interconnect structure 140. Thus, if the first portion of the through-substrate interconnect structure 140 is formed to a thickness that is less than approximately 0.5 microns, the dielectric insert(s) 146 may be located too close to the sidewalls of the through-substrate interconnect structure 140 and may not sufficiently withstand dishing in the through-substrate interconnect structure 140. However, if the first portion of the through-substrate interconnect structure 140 is formed to a thickness that is greater than approximately 5 microns, the remaining area in the recess 304 may be too small to achieve high gap-filling performance when filling in the remaining area with additional material of the through-substrate interconnect structure 140. However, other values, and ranges other than approximately 0.5 microns to approximately 5 microns, are within the scope of the present disclosure.

As shown in FIG. 3F, a dielectric layer 306 is conformally deposited over the first portion of the through-substrate interconnect structure 140 on the sidewalls and on the bottom surface of the recess 304. A deposition tool may be used to deposit the dielectric layer 306 using an ALD technique, a CVD technique, an electroplating technique, and/or another suitable deposition technique. The material of the dielectric layer 306 may also deposited along the front side surface of the substrate layer of the device layer 112, as shown in the example in FIG. 3F.

As shown in FIG. 3G, an etch operation may be performed to trim portions of the dielectric layer 306. In particular, a directional (e.g., vertical) etch may be performed to selectively remove material of the dielectric layer 306 from the front side surface of the substrate layer of the device layer 112 and from the bottom surface of the recess 304. An etch tool may be used to perform a plasma-based etch operation or another type of anisotropic etch so that portions of the dielectric layer 306 remain on the sidewalls of the recess 304 as the dielectric insert(s) 146.

As shown in FIG. 3H, a second portion of the through-substrate interconnect structure 140 may be formed in the recess 304 after formation of the dielectric insert(s) 146. The second portion of the through-substrate interconnect structure 140 may include another layer of electrically conductive material that fills in the remaining area of the recess 304. In some implementations, the second portion of the through-substrate interconnect structure 140 is formed using a deposition tool to by forming another layer of electroplated copper in the recess 304. In some implementations, the second portion of the through-substrate interconnect structure 140 is formed using another deposition technique.

As shown in FIG. 3I, a planarization tool may be used to perform a first planarization operation (e.g., a first CMP operation) to remove excess material of the through-substrate interconnect structure 140 the front side of the substrate layer of the device layer 112. In some implementations, the first planarization operation may be performed until the excess material of the liners 142 and/or 144 on the front side surface of the 302 substrate layer of the device layer 112 is reached. The dielectric insert(s) 146 may also be planarized along with the through-substrate interconnect structure 140 during the first planarization operation.

As shown in FIG. 3J, a planarization tool may be used to perform a second planarization operation (e.g., a second CMP operation) to remove excess material of the liners 142 and/or 144 from the front side of the substrate layer of the device layer 112. In some implementations, the second planarization operation may be performed until the hard mask layer 302 is reached. The dielectric insert(s) 146 may also be planarized during the second planarization operation.

The dielectric insert(s) 146 formed in the through-substrate interconnect structure 140 prevent, minimize, and/or otherwise reduce the likelihood of dishing in the top surface of the through-substrate interconnect structure 140 that might otherwise result from the second planarization operation. Dishing might otherwise result in the top surface of the through-substrate interconnect structure 140 becoming concave and being below the front side surface of the substrate layer of the device layer 112. This might otherwise result in removal of portions of the liners 142 and/or 144 at the top of the through-substrate interconnect structure 140, thereby increasing the likelihood of current leakage and/or material migration from the top of the through-substrate interconnect structure 140. In this way, the dielectric insert(s) 146 prevent, minimize, and/or otherwise reduce the likelihood of removal of portions of the liners 142 and/or 144 at the top of the through-substrate interconnect structure 140, thereby reducing the likelihood of current leakage and/or material migration from the top of the through-substrate interconnect structure 140.

As shown in FIG. 3K, the interconnect layer 114 may be formed above the device layer 112 (and above the through-substrate interconnect structure 140). One or more semiconductor processing tools may be used to form the interconnect layer 114 by forming one or more dielectric layers 126 and forming a plurality of conductive structures 128 in the dielectric layer(s) 126. For example, a deposition tool may be used to deposit a first layer of the dielectric layer(s) 126 (e.g., using a CVD technique, an ALD technique, a PVD technique, an oxidation technique, and/or another type of deposition technique), an etch tool may be used to remove portions of the first layer to form recesses in the first layer, and a deposition tool may be used to form a first layer (e.g., a via layer, a metallization layer) of one or more conductive structures 128 in the recesses (e.g., using a CVD technique, an ALD technique, a PVD technique, an electroplating technique, and/or another type of deposition technique). At least a portion of the first layer of conductive structures 128 may be electrically connected and/or physically connected with the integrated circuit devices 118 in the device layer 112 (e.g., directly connected or connected through contacts). Similar processing operations may be performed to form additional layers of the interconnect layer 114 until a sufficient or desired arrangement of conductive structures 128 is achieved.

As further shown in FIG. 3K, a conductive structure 128 in the interconnect layer 114 may be formed on the through-substrate interconnect structure 140 such that the conductive structure 128 is electrically coupled and/or physically coupled to the through-substrate interconnect structure 140.

As further shown in FIG. 3K, the bonding pads 130 may be formed in a dielectric layer 126 of the interconnect layer 114. In some implementations, one or more bonding pads 130 may be electrically connected to one or more conductive structures 128 in the interconnect layer 114 by bonding vias.

As indicated above, FIGS. 3A-3H are provided as an example. Other examples may differ from what is described with regard to FIGS. 3A-3H.

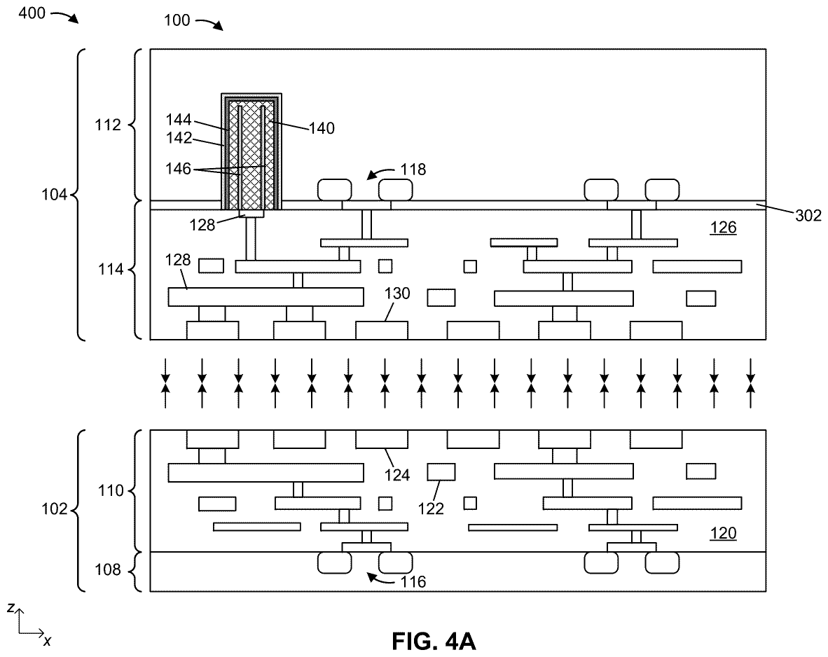

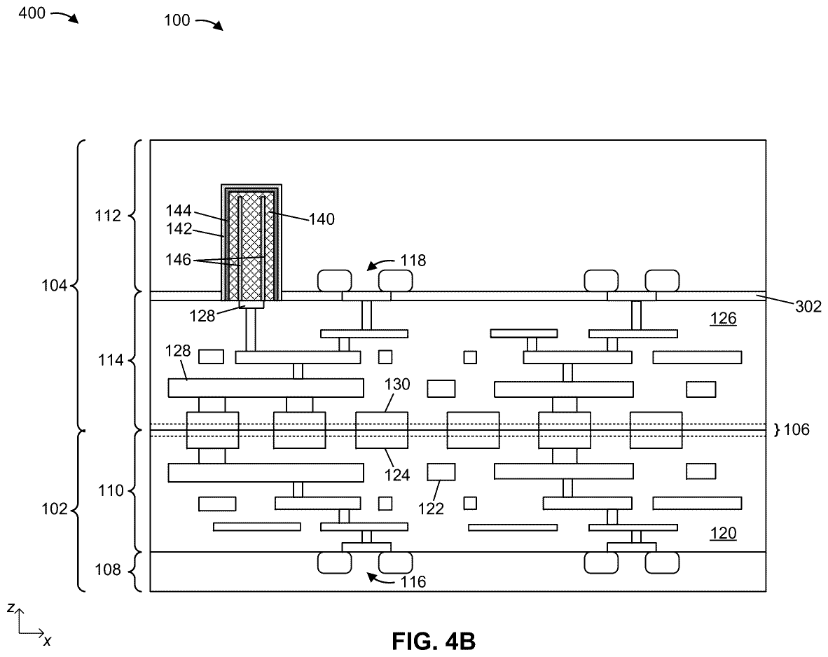

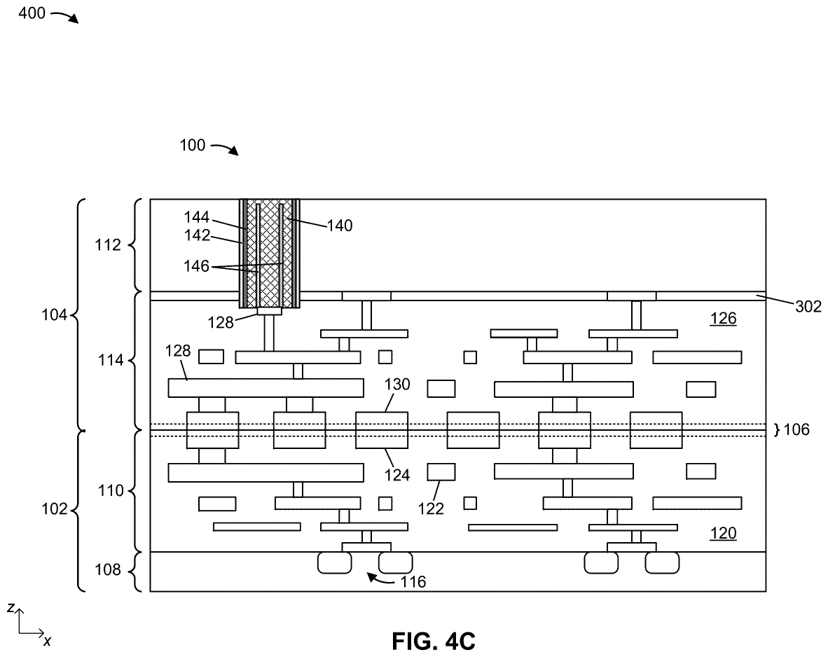

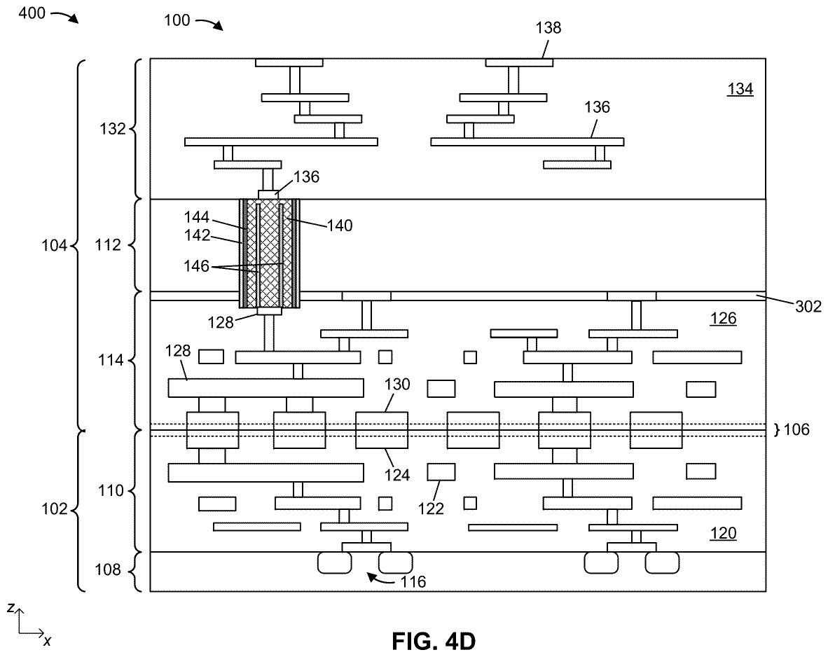

FIGS. 4A-4D are diagrams of an example implementation 400 of forming a semiconductor package described herein. For example, the example implementation 400 may include an example of forming a semiconductor package 100. In some implementations, one or more semiconductor processing tools may be used to perform one or more of the operations described in connection with the example implementation 400, such as bonding tool, a deposition tool, an exposure tool, a developer tool, an etch tool, a planarization tool, a plating tool, and/or another type of semiconductor processing tool.

As shown in FIGS. 4A and 4B, a bonding operation is performed to bond the semiconductor die 102 and the semiconductor die 104 at the bonding interface 106 such that the semiconductor die 102 and the semiconductor die 104 are vertically arranged or stacked in the semiconductor package 100. The semiconductor die 102 and the semiconductor die 104 may be vertically arranged or stacked in a wafer on wafer (WoW) configuration, a die on wafer configuration, a die on die configuration, and/or another direct bonding configuration. In some implementations, the semiconductor die 102 and the semiconductor die 104 may be bonded together after forming the through-substrate interconnect structure 140 in the semiconductor die 104.

A bonding tool may be used to perform the bonding operation to bond the semiconductor die 102 and the semiconductor die 104 at the bonding interface 106. The bonding operation may include forming a direct bond between the semiconductor die 102 and the semiconductor die 104 through a direct physical connection of the bonding pads 124 of the semiconductor die 102 with the bonding pads 130 of the semiconductor die 104, and through a direct physical connection of one or more of the dielectric layers 120 of the semiconductor die 102 with one or more dielectric layers 126 of the semiconductor die 104.

As shown in FIG. 4C, back side processing may be performed on the back side of the device layer 112 after bonding the semiconductor dies 102 and 104 at the bonding interface 106. The back side processing may include using a planarization tool (e.g., a wafer grinding tool) to perform a planarization operation (e.g., a wafer grinding operation) to remove material from the back side of the device layer 112. The through-substrate interconnect structure 140 may be formed partially into the device layer 112. Thus, after bonding, the through-substrate interconnect structure 140 does not extend all the way through the device layer 112 to the back side of the device layer 112. Accordingly, the planarization operation may be performed to remove material from the back side of the device layer 112 to expose the bottom of the through-substrate interconnect structure 140 (e.g., the second end of the through-substrate interconnect structure 140) through the device layer 112. The planarization operation may result in the bottom of the through-substrate interconnect structure 140 being approximately co-planar with the back side surface of the device layer 112.

In some implementations, the planarization operation stops before the bottoms of the dielectric insert(s) 146 are exposed through the bottom of the through-substrate interconnect structure 140. In some implementations, the planarization operation removes material from the through-substrate interconnect structure 140 until (or stops after) the dielectric insert(s) 146 are exposed. In these implementations, the dielectric insert(s) 146 prevent, minimize, and/or reduce the likelihood of dishing in the second end of the through-substrate interconnect structure 140 that might otherwise occur during planarization of the back side of the device layer 112.

As shown in FIG. 4D, the interconnect layer 132 may be formed above the back side of the device layer 112. One or more semiconductor processing tools may be used to form the interconnect layer 132 by forming one or more dielectric layers 134 and forming a plurality of conductive structures 136 in the dielectric layer(s) 134. For example, a deposition tool may be used to deposit a first layer of the dielectric layer(s) 134 (e.g., using a CVD technique, an ALD technique, a PVD technique, an oxidation technique, and/or another type of deposition technique), an etch tool may be used to remove portions of the first layer to form recesses in the first layer, and a deposition tool may be used to form a first layer (e.g., a via layer, a metallization layer) of one or more conductive structures 136 in the recesses (e.g., using a CVD technique, an ALD technique, a PVD technique, an electroplating technique, and/or another type of deposition technique). Similar processing operations may be performed to form additional layers of the interconnect layer 132 until a sufficient or desired arrangement of conductive structures 136 is achieved.

As further shown in FIG. 4D, one or more of the conductive structures 136 in the interconnect layer 132 may be formed on the bottom of the through-substrate interconnect structure 140. The conductive structure 136 may be electrically connected and/or physically connected with the through-substrate interconnect structure 140.

As further shown in FIG. 4D, the connection structures 138 of the interconnect layer 132 may be formed in a dielectric layer 134. In some implementations, one or more connection structures 138 may be electrically connected to one or more conductive structures 136 in the interconnect layer 132.

As indicated above, FIGS. 4A-4D are provided as an example. Other examples may differ from what is described with regard to FIGS. 4A-4D.

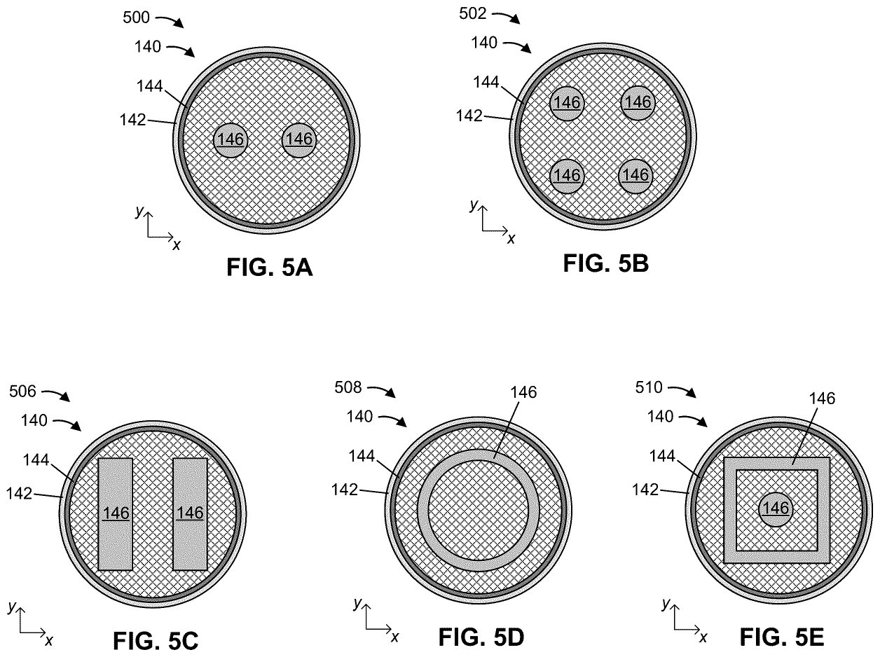

FIGS. 5A-5E are diagram of example implementations of top view layouts for dielectric inserts 146 in a through-substrate interconnect structure 140 described herein. The example top view layouts illustrates in FIGS. 5A-5E are examples, and other top view layouts for dielectric inserts 146 in a through-substrate interconnect structure 140 are within the scope of the present disclosure.

FIG. 5A illustrates an example implementation 500 of a top view layout for dielectric inserts 146 in a through-substrate interconnect structure 140. As shown in FIG. 5A, a plurality of dielectric inserts 146 may be located within a perimeter of the through-substrate interconnect structure 140. The dielectric inserts 146 may include dielectric pillars, dielectric plugs, and/or dielectric vias, among other examples. The dielectric inserts 146 may be spaced apart from each other such that a portion of the through-substrate interconnect structure 140 is located between the dielectric inserts 146. Other portions of the through-substrate interconnect structure 140 may be located between the dielectric inserts 146 and the liners 142 and/or 144 around the through-substrate interconnect structure 140.

FIG. 5B illustrates an example implementation 502 of a top view layout for dielectric inserts 146 in a through-substrate interconnect structure 140. As shown in FIG. 5B, a plurality of dielectric inserts 146 may be located within a perimeter of the through-substrate interconnect structure 140. The dielectric inserts 146 may include dielectric pillars, dielectric plugs, and/or dielectric vias, among other examples. The dielectric inserts 146 may be spaced apart from each other such that a portion of the through-substrate interconnect structure 140 is located between the dielectric inserts 146. The dielectric inserts 146 may be distributed in the x-direction and/or in the y-direction within the perimeter of the through-substrate interconnect structure 140. In the example in FIG. 5B, the dielectric inserts 146 are arranged in a grid. However, other arrangements for the dielectric inserts 146 are within the scope of the present disclosure.

FIG. 5C illustrates an example implementation 506 of a top view layout for dielectric inserts 146 in a through-substrate interconnect structure 140. As shown in FIG. 5C, a plurality of dielectric inserts 146 may be located within a perimeter of the through-substrate interconnect structure 140. The dielectric inserts 146 may include dielectric trenches and/or another type of dielectric structures that are elongated in the x-direction (or that are elongated in the y-direction). In some implementations, the dielectric inserts 146 are elongated in a first lateral direction (e.g., the y-direction) and are arranged in a second lateral direction (e.g., the x-direction).

FIG. 5D illustrates an example implementation 508 of a top view layout for a dielectric insert 146 in a through-substrate interconnect structure 140. As shown in FIG. 5D, a single dielectric insert 146 may be located within a perimeter of the through-substrate interconnect structure 140. The dielectric insert 146 has a top view shape that is substantially ring-shaped. Thus, the dielectric insert 146 may have a cylindrical shell (e.g., a hollow cylinder) or tube three-dimensional shape since the dielectric insert 146 extends in the z-direction in the through-substrate interconnect structure 140. However, other types of closed-loop top view shapes (e.g., square-shaped, triangular-shaped, rectangular-shaped) for dielectric inserts 146 are within the scope of the present disclosure.

FIG. 5E illustrates an example implementation 510 of a top view layout for dielectric inserts 146 in a through-substrate interconnect structure 140. As shown in FIG. 5E, a plurality of dielectric inserts 146 may be located within a perimeter of the through-substrate interconnect structure 140. The dielectric inserts 146 may have different top view shapes. For example, a first dielectric insert 146 may be a dielectric pillar and may have a circle top view shape, and a second dielectric insert 146 may have a closed-loop top view shape. The first dielectric insert 146 may be located within the second dielectric insert 146 in the top view of the through-substrate interconnect structure 140. However, other top view arrangements for the first and second dielectric inserts 146 are within the scope of the present disclosure.

As indicated above, FIGS. 5A-5E are provided as examples. Other examples may differ from what is described with regard to FIGS. 5A-5E.

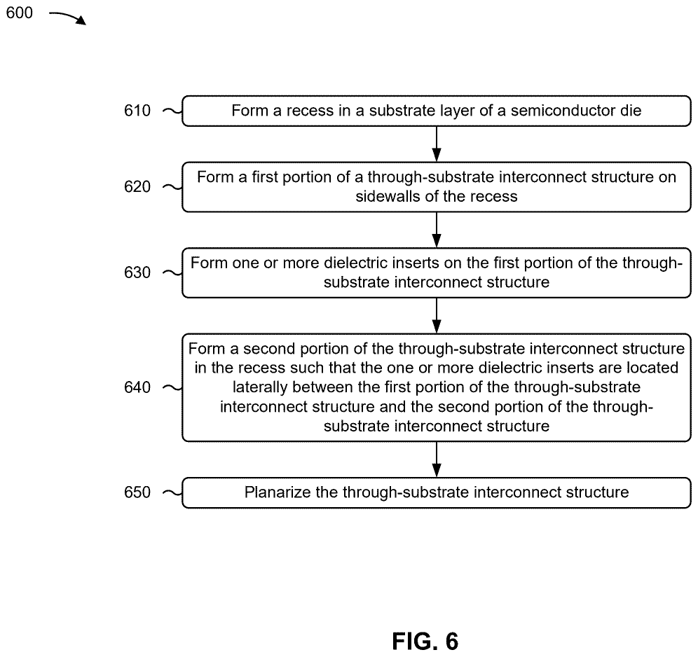

FIG. 6 is a flowchart of an example process 600 associated with forming a semiconductor die described herein. In some implementations, one or more process blocks of FIG. 6 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 6, process 600 may include forming a recess in a substrate layer of a semiconductor die (block 610). For example, one or more semiconductor processing tools may be used to form a recess (e.g., a recess 304) in a substrate layer (e.g., a device layer 112) of a semiconductor die (e.g., a semiconductor die 104), as described herein.

As further shown in FIG. 6, process 600 may include forming a first portion of a through-substrate interconnect structure on sidewalls of the recess (block 620). For example, one or more semiconductor processing tools may be used to form a first portion of a through-substrate interconnect structure (e.g., a through-substrate interconnect structure 140) on sidewalls of the recess, as described herein.

As further shown in FIG. 6, process 600 may include forming one or more dielectric inserts (146) on the first portion of the through-substrate interconnect structure (block 630). For example, one or more semiconductor processing tools may be used to form one or more dielectric inserts (e.g., dielectric inserts 146) on the first portion of the through-substrate interconnect structure, as described herein.

As further shown in FIG. 6, process 600 may include forming a second portion of the through-substrate interconnect structure in the recess such that the one or more dielectric inserts are located laterally between the first portion of the through-substrate interconnect structure and the second portion of the through-substrate interconnect structure (block 640). For example, one or more semiconductor processing tools may be used to form a second portion of the through-substrate interconnect structure in the recess such that the one or more dielectric inserts are located laterally between the first portion of the through-substrate interconnect structure and the second portion of the through-substrate interconnect structure, as described herein.

As further shown in FIG. 6, process 600 may include planarizing the through-substrate interconnect structure (block 650). For example, one or more semiconductor processing tools may be used to planarize the through-substrate interconnect structure, as described herein.

Process 600 may include additional implementations, such as any single implementation or any combination of implementations described below and/or in connection with one or more other processes described elsewhere herein.

In a first implementation, process 600 includes planarizing the one or more dielectric inserts along with the through-substrate interconnect structure.

In a second implementation, alone or in combination with the first implementation, forming the first portion of the through-substrate interconnect structure includes forming the first portion of the through-substrate interconnect structure such that the first portion of the through-substrate interconnect structure conforms to the sidewalls and to a bottom surface of the recess, and wherein forming the one or more dielectric inserts includes forming a dielectric layer (e.g., a dielectric layer 306) on the first portion of the through-substrate interconnect structure, and etching a first portion of the dielectric layer on the first portion of the through-substrate interconnect structure that is located on the bottom surface of the recess, wherein second portions of the dielectric layer remaining on the first portion of the through-substrate interconnect structure correspond to the one or more dielectric inserts.

In a third implementation, alone or in combination with one or more of the first and second implementations, forming the first portion of the through-substrate interconnect structure includes forming the first portion of the through-substrate interconnect structure to a thickness that is included in a range of approximately 5 nanometers to approximately 5000 nanometers.

In a fourth implementation, alone or in combination with one or more of the first through third implementations, forming the one or more dielectric inserts includes forming the one or more dielectric inserts each to a lateral thickness that is included in a range of approximately 10 angstroms to approximately 1000 angstroms.

In a fifth implementation, alone or in combination with one or more of the first through fourth implementations, process 600 includes forming one or more liners (e.g., a liner 142, a liner 144) in the recess, and forming the first portion of the through-substrate interconnect structure includes forming the first portion of the through-substrate interconnect structure on the one or more liners in the recess.

In a sixth implementation, alone or in combination with one or more of the first through fifth implementations, forming the one or more dielectric inserts includes forming a dielectric insert, of the one or more dielectric inserts, such that a vertical height (e.g., dimension D1) of the dielectric insert is greater than a lateral width (e.g., dimension D5) of the dielectric insert.

Although FIG. 6 shows example blocks of process 600, in some implementations, process 600 includes additional blocks, fewer blocks, different blocks, or differently arranged blocks than those depicted in FIG. 6. Additionally, or alternatively, two or more of the blocks of process 600 may be performed in parallel.

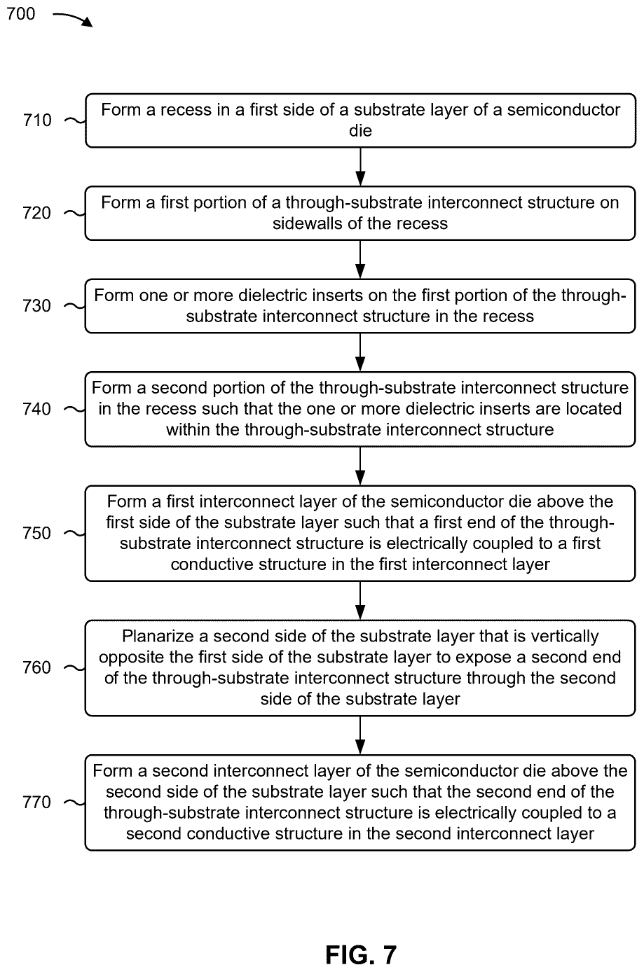

FIG. 7 is a flowchart of an example process 700 associated with forming a semiconductor die described herein. In some implementations, one or more process blocks of FIG. 7 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 7, process 700 may include forming a recess (304) in a first side of a substrate layer of a semiconductor die (block 710). For example, one or more semiconductor processing tools may be used to form a recess (e.g., a recess 304) in a first side of a substrate layer (e.g., a device layer 112) of a semiconductor die (e.g., a semiconductor die 104), as described herein.

As further shown in FIG. 7, process 700 may include forming a first portion of a through-substrate interconnect structure on sidewalls of the recess (block 720). For example, one or more semiconductor processing tools may be used to form a first portion of a through-substrate interconnect structure (e.g., a through-substrate interconnect structure 140) on sidewalls of the recess, as described herein.

As further shown in FIG. 7, process 700 may include forming one or more dielectric inserts on the first portion of the through-substrate interconnect structure in the recess (block 730). For example, one or more semiconductor processing tools may be used to form one or more dielectric inserts (e.g., one or more dielectric inserts 146) on the first portion of the through-substrate interconnect structure in the recess, as described herein.

As further shown in FIG. 7, process 700 may include forming a second portion of the through-substrate interconnect structure in the recess such that the one or more dielectric inserts are located within the through-substrate interconnect structure (block 740). For example, one or more semiconductor processing tools may be used to form a second portion of the through-substrate interconnect structure in the recess such that the one or more dielectric inserts are located within the through-substrate interconnect structure, as described herein.

As further shown in FIG. 7, process 700 may include forming a first interconnect layer of the semiconductor die above the first side of the substrate layer such that a first end of the through-substrate interconnect structure is electrically coupled to a first conductive structure in the first interconnect layer (block 750). For example, one or more semiconductor processing tools may be used to form a first interconnect layer (e.g., an interconnect layer 114) of the semiconductor die above the first side of the substrate layer such that a first end of the through-substrate interconnect structure is electrically coupled to a first conductive structure (e.g., a conductive structure 128) in the first interconnect layer, as described herein.

As further shown in FIG. 7, process 700 may include planarizing a second side of the substrate layer that is vertically opposite the first side of the substrate layer to expose a second end of the through-substrate interconnect structure through the second side of the substrate layer (block 760). For example, one or more semiconductor processing tools may be used to planarize a second side of the substrate layer that is vertically opposite the first side of the substrate layer to expose a second end of the through-substrate interconnect structure through the second side of the substrate layer, as described herein.

As further shown in FIG. 7, process 700 may include forming a second interconnect layer of the semiconductor die above the second side of the substrate layer such that the second end of the through-substrate interconnect structure is electrically coupled to a second conductive structure in the second interconnect layer (block 770). For example, one or more semiconductor processing tools may be used to form a second interconnect layer (e.g., an interconnect layer 132) of the semiconductor die above the second side of the substrate layer such that the second end of the through-substrate interconnect structure is electrically coupled to a second conductive structure (e.g., a conductive structure 136) in the second interconnect layer, as described herein.

Process 700 may include additional implementations, such as any single implementation or any combination of implementations described below and/or in connection with one or more other processes described elsewhere herein.

In a first implementation, process 700 includes planarizing the second end of the through-substrate interconnect structure while planarizing the second side of the substrate layer.

In a second implementation, alone or in combination with the first implementation, planarizing the second end of the through-substrate interconnect structure includes removing one or more liners (e.g., a liner 142, a liner 144) from the second end of the through-substrate interconnect structure to expose the second end of the through-substrate interconnect structure.

In a third implementation, alone or in combination with one or more of the first and second implementations, planarizing the second end of the through-substrate interconnect structure includes removing material from the second end of the through-substrate interconnect structure to expose the one or more dielectric inserts through the second side of the substrate layer.

In a fourth implementation, alone or in combination with one or more of the first through third implementations, planarizing the second end of the through-substrate interconnect structure includes planarizing the second end of the through-substrate interconnect structure such that the second end of the through-substrate interconnect structure remains over the one or more dielectric inserts.

In a fifth implementation, alone or in combination with one or more of the first through fourth implementations, forming the one or more dielectric inserts includes forming a plurality of dielectric pillars that are spaced apart from each other within the through-substrate interconnect structure.

In a sixth implementation, alone or in combination with one or more of the first through fifth implementations, forming the one or more dielectric inserts includes forming a dielectric insert, of the one or more dielectric inserts, such that a ratio of a vertical height (e.g., a dimension D1) of the dielectric insert to a lateral width (e.g., a dimension D5) of the dielectric insert is greater than a ratio of a vertical height (e.g., a dimension D1) of the through-substrate interconnect structure to a lateral width (e.g., a dimension D2) of the through-substrate interconnect structure.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

In this way, one or more dielectric inserts are formed in a through-substrate interconnect structure to prevent, minimize, and/or otherwise reduce the amount of dishing that occurs in the top surface of the through-substrate interconnect structure during planarization of the through-substrate interconnect structure. The dielectric insert(s) are formed of a dielectric material having a hardness that is greater than the hardness of the metal material of the through-substrate interconnect structure. The greater hardness enables the dielectric insert(s) to resist material removal during planarization of the through-substrate interconnect structure, which enables a high uniformity in the material removal rates across the top surface of the through-substrate interconnect structure to be achieved. The reduced amount of dishing during planarization of the through-substrate interconnect structure reduces the likelihood of removal of liner material from one or more liners between the sidewalls of the through-substrate interconnect structure and the substrate layer. In this way, the dielectric insert(s) reduce the likelihood of current leakage from the through-substrate interconnect structure into the substrate layer.

As described in greater detail above, some implementations described herein provide a method. The method includes etching a substrate layer of a semiconductor die to form a recess in the substrate layer. The method includes depositing a first portion of a through-substrate interconnect structure on sidewalls of the recess. The method includes forming one or more dielectric inserts on the first portion of the through-substrate interconnect structure. The method includes depositing a second portion of the through-substrate interconnect structure in the recess such that the one or more dielectric inserts are located laterally between the first portion of the through-substrate interconnect structure and the second portion of the through-substrate interconnect structure. The method includes planarizing the through-substrate interconnect structure.

As described in greater detail above, some implementations described herein provide a method. The method includes etching a substrate layer of a semiconductor die to form a recess in a first side of the substrate layer. The method includes depositing a first portion of a through-substrate interconnect structure on sidewalls of the recess. The method includes forming one or more dielectric inserts on the first portion of the through-substrate interconnect structure in the recess. The method includes depositing a second portion of the through-substrate interconnect structure in the recess such that the one or more dielectric inserts are located within the through-substrate interconnect structure. The method includes forming a first interconnect layer of the semiconductor die above the first side of the substrate layer such that a first end of the through-substrate interconnect structure is electrically coupled to a first conductive structure in the first interconnect layer. The method includes planarizing a second side of the substrate layer that is vertically opposite the first side of the substrate layer to expose a second end of the through-substrate interconnect structure through the second side of the substrate layer. The method includes forming a second interconnect layer of the semiconductor die above the second side of the substrate layer such that the second end of the through-substrate interconnect structure is electrically coupled to a second conductive structure in the second interconnect layer.

As described in greater detail above, some implementations described herein provide a semiconductor die. The semiconductor die includes a substrate layer. The semiconductor die includes a first interconnect layer vertically adjacent to a first side of the substrate layer. The semiconductor die includes a second interconnect layer vertically adjacent to a second side of the substrate layer opposing the first side. The semiconductor die includes a through-substrate interconnect structure extending through the substrate layer between the first interconnect layer and the second interconnect layer. The semiconductor die includes one or more dielectric inserts extending through the through-substrate interconnect structure.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
etching a substrate layer of a semiconductor die to form a recess in the substrate layer ;
depositing a first portion of a through-substrate interconnect structure on sidewalls of the recess;
forming one or more dielectric inserts on the first portion of the through-substrate interconnect structure;
depositing a second portion of the through-substrate interconnect structure in the recess such that the one or more dielectric inserts are located laterally between the first portion of the through-substrate interconnect structure and the second portion of the through-substrate interconnect structure; and
planarizing the through-substrate interconnect structure.

2. The method of claim 1, further comprising:
planarizing the one or more dielectric inserts along with the through-substrate interconnect structure.

3. The method of claim 1, wherein depositing the first portion of the through-substrate interconnect structure comprises:
depositing the first portion of the through-substrate interconnect structure such that the first portion of the through-substrate interconnect structure conforms to the sidewalls and to a bottom surface of the recess; and
wherein forming the one or more dielectric inserts comprises:
forming a dielectric layer on the first portion of the through-substrate interconnect structure; and
etching a first portion of the dielectric layer on the first portion of the through-substrate interconnect structure that is located on the bottom surface of the recess,
wherein second portions of the dielectric layer remaining on the first portion of the through-substrate interconnect structure correspond to the one or more dielectric inserts.

4. The method of claim 1, wherein depositing the first portion of the through-substrate interconnect structure comprises:
depositing the first portion of the through-substrate interconnect structure to a thickness that is included in a range of approximately 0.5 microns to approximately 5 microns.

5. The method of claim 1, wherein forming the one or more dielectric inserts comprises:
forming the one or more dielectric inserts each to a lateral thickness that is included in a range of approximately 10 angstroms to approximately 1000 angstroms.

6. The method of claim 1, further comprising:
depositing one or more liners in the recess,
wherein depositing the first portion of the through-substrate interconnect structure comprises:
depositing the first portion of the through-substrate interconnect structure on the one or more liners in the recess.

7. The method of claim 1, wherein forming the one or more dielectric inserts comprises:
forming a dielectric insert, of the one or more dielectric inserts, such that a vertical height of the dielectric insert is greater than a lateral width of the dielectric insert.

8. A method, comprising:
Etching a substrate layer of semiconductor device to forma recess in a first side of the substrate layer;
depositing a first portion of a through-substrate interconnect structure on sidewalls of the recess;
forming one or more dielectric inserts on the first portion of the through-substrate interconnect structure in the recess; and
depositing a second portion of the through-substrate interconnect structure in the recess such that the one or more dielectric inserts are located within the through-substrate interconnect structure;
forming a first interconnect layer of the semiconductor die above the first side of the substrate layer such that a first end of the through-substrate interconnect structure is electrically coupled to a first conductive structure in the first interconnect layer;
planarizing a second side of the substrate layer that is vertically opposite the first side of the substrate layer to expose a second end of the through-substrate interconnect structure through the second side of the substrate layer; and
forming a second interconnect layer of the semiconductor die above the second side of the substrate layer such that the second end of the through-substrate interconnect structure is electrically coupled to a second conductive structure in the second interconnect layer.

9. The method of claim 8, further comprising:
planarizing the second end of the through-substrate interconnect structure while planarizing the second side of the substrate layer.

10. The method of claim 9, wherein planarizing the second end of the through-substrate interconnect structure comprises:
removing one or more liners from the second end of the through-substrate interconnect structure to expose the second end of the through-substrate interconnect structure.

11. The method of claim 9, wherein planarizing the second end of the through-substrate interconnect structure comprises:
removing material from the second end of the through-substrate interconnect structure to expose the one or more dielectric inserts through the second side of the substrate layer.

12. The method of claim 9, wherein planarizing the second end of the through-substrate interconnect structure comprises:
planarizing the second end of the through-substrate interconnect structure such that the second end of the through-substrate interconnect structure remains over the one or more dielectric inserts.

13. The method of claim 8, wherein forming the one or more dielectric inserts comprises:
forming a plurality of dielectric pillars that are spaced apart from each other within the through-substrate interconnect structure.

14. The method of claim 8, wherein forming the one or more dielectric inserts comprises:
forming a dielectric insert, of the one or more dielectric inserts, such that a ratio of a vertical height of the dielectric insert to a lateral width of the dielectric insert is greater than a ratio of a vertical height of the through-substrate interconnect structure to a lateral width of the through-substrate interconnect structure.

15. A semiconductor die, comprising:
a substrate layer;
a first interconnect layer vertically adjacent to a first side of the substrate layer;
a second interconnect layer vertically adjacent to a second side of the substrate layer opposing the first side;
a through-substrate interconnect structure extending through the substrate layer between the first interconnect layer and the second interconnect layer; and
one or more dielectric inserts extending through the through-substrate interconnect structure.

16. The semiconductor of claim 15, wherein the one or more dielectric inserts comprise a plurality of dielectric pillars that are elongated in a vertical direction in the semiconductor die.

17. The semiconductor of claim 15, wherein the one or more dielectric inserts comprise a dielectric ring extending through the through-substrate interconnect structure.

18. The semiconductor of claim 15, wherein the one or more dielectric inserts comprise a plurality of dielectric columns that are elongated in a vertical direction in the semiconductor die and are elongated in a lateral direction approximately perpendicular to the vertical direction.

19. The semiconductor of claim 15, wherein the one or more dielectric inserts comprise:
a closed-loop dielectric ring extending through the through-substrate interconnect structure; and
a dielectric pillar that is elongated in a vertical direction in the semiconductor die,
wherein the dielectric pillar is located within a perimeter of the closed-loop dielectric ring.

20. The semiconductor of claim 15, wherein a lateral width of a dielectric insert of the one or more dielectric inserts is less than a lateral width of a liner between the substrate layer and the through-substrate interconnect structure.
